(19) United States
(12) Patent Application Publication
(10) Pub. No.: US 2006/0145169 A1
(43) Pub. Date: Jul. 6, 2006

(54) Light emitting diode

(75) Inventors: Te-Chung Wang, Hsinchu (TW); Chang-cheng Chuo, Hsinchu (TW); Jung-Chieh Su, Hsinchu (TW); Ching-En Tsai, Hsinchu (TW); Cheng-Hong Lee, Hsinchu (TW)

Correspondence Address: BIRCH STEWART KOLASCH & BIRCH, PO BOX 747, FALLS CHURCH, VA, 22040-0747, US

(73) Assignee: INDUSTRIAL TECHNOLOGY RESEARCH INSTITUTE

(21) Appl. No.: 11/155,774

(22) Filed: Jun. 20, 2005

(30) Foreign Application Priority Data
Dec. 30, 2004 (TW) 93141535

(51) Int. Cl. H01L 33/00

(52) U.S. Cl. 257/89; 257/98; 257/E33.061

(57) ABSTRACT

A light emitting diode (LED) is added aluminum atom in every layer of InGaN light emitting diode to emit a UV light with wavelength between 300 nm and 380 nm which is not able to see by humans. This LED can co-operate with different colors of luminescent material layer or quantum well/quantum dot structures to emit different color (wavelength) of light, which are different colors (wavelengths) of LED.

### BACKGROUND

1. Field of Invention

The invention relates to a light emitting diode (LED) and, in particular, to a light emitting diode which emits light whose wavelength is between 300˜380 nm, and uses the excited UV light to excite and form a visual light.

2. Related Art

Light emitting diode (LED) is one kind of semiconductor luminescence device. It only needs an extremely small current for emitting light and that is different from the conventional incandescent lamp which needs high current to heat the filament for emitting light. Its concept of lighting is electron-hole combination mechanism of semiconductor materials. According to the mechanism, light emits while energy releases. LED has several advantages, such as small size, long life span, low driving voltage, low power consumption, high responding speed, good shock resistance and good monochromaticity, which make it apply to electronics, electronic information board, and communication devices as a luminescence device. Several monochromatic lights can be obtained by the design and control of LED chip process.

Because of the power saving characteristic of LED, it is expected that it can be used for replacing light bulbs in some applications in the future. However, presently the price and luminosity of white light LED haven't met the requirement of popularization, which makes white light LED become a long term key research in the LED industry. Most of LED products used to emit white light now are using a light mixing method, in which a yellow light is produced by using a blue light LED to excite yellow luminescent material, and a blue light is obtained from the blue light LED and then two lights mix together. Along with the improvement of luminosity of blue light LED, the application of white light LED product is getting wider and wider.

Development of high luminosity LED activates the LED industry, especially a successful development of blue-green LED. The luminosity efficiency is improving day by day. The luminosity obtained can reach to several candlepower, and keep rising. And because the luminosity of blue light LED is getting higher, the application of white light LED product which emits light by mixing in the market is growing. However, because the white light is produced by mixing blue light and yellow light, it is hard to control the tinges of white color. White light produced may be a white mixing with a little green or a white mixing with yellow. That is, it has un-uniform color temperature.

Now on, a well commercialized product of white light LED is developed by Japan Company NICHIA. A diagram of the device is shown in FIG. 1. In the drawing, the device includes a layer of yttrium aluminum garnet (YAG) 20 coated on a blue light LED 10 which has emitting wavelength of 460 nm. The device uses light produced from the blue light LED to excite the yttrium aluminum garnet (YAG) layer for producing a 555 nm yellow light which is a complementary light of blue light. Next, lens is used to mix the blue light and yellow light such that a white light can be obtained. White light LED made by this method costs less and the circuit design is much easy.

However, NICHIA Company own the patent of above process, therefore, most company now focus on the development of three wavelengths light. Three wavelengths light is produced by using an UV light which is generated by an inorganic UV emitting chip to excite blue, green and red luminescent materials. If the proportion of three wavelength light is carefully adjusted, the light mixed will be white light.

Practically, light produced by the UV emitting chip of above techniques is not pure UV light. Researchers think that as long as the wavelength of light emitted by an LED chip is between 400 nm and 470 nm, the LED chip can be considered as a UV light emitting chip. However, light with wavelength larger than 380 nm still can be seen by human eyes, therefore it will interfere with the light it supposed to excite, which makes pure white light not available.

### SUMMARY

According the reasons above, one objective of the invention is to provide a light emitting diode (LED), which emits a UV light with wavelength between 300 nm and 380 nm by adding aluminum atom in every layer of InGaN light emitting diode.

In order to achieve the above objective, a light emitting diode which is disclosed comprises: a substrate, a nucleation layer, a buffer layer, a n-type contact layer, a n-type cover layer, a light emitting layer, a p-type barrier layer, a p-type cover layer and a p-type contact layer.

The substrate is consisted of a material adapted for epitaxy. The nucleation layer is formed on the substrate and consisted of AlₓGa₁₋ₓN for preventing from the un-match of crystal lattice, wherein 0≦x≦1.

The buffer layer is formed on the nucleation layer. It can be consisted of ud-AlₓGa₁₋ₓN or n-AlₓGa₁₋ₓN, wherein 0≦x≦0.3. The n-type contact layer is formed on the buffer layer and electrically connects to an n-type electrode. The n-type contact layer is consisted of n-AlₓGa₁₋ₓN, wherein 0≦x≦0.3.

The n-type cover layer is formed on the n-type contact layer. It can be consisted of n-AlₓGa₁₋ₓN, wherein 0≦x≦0.3. The light emitting layer is formed on the n-type cover layer, which is used for emitting light in the LED. The light emitting layer can be an In_{y}AlₓGa_{1-x-y}N/In_{y}AlₓGa_{1-x-y}N quantum well/quantum dot structure, wherein 0≦x≦0.3, 0≦y≦0.2.

The p-type barrier layer is formed on the light emitting layer for preventing carriers from overflowing. The p-type barrier layer can be consisted of p-AlₓGa₁₋ₓN, wherein 0≦x≦0.4. The p-type cover layer is formed on the p-type barrier layer for confining carriers and can be consisted of p-AlₓGa₁₋ₓN, wherein 0≦x≦0.3. The p-type contact layer is formed on the p-type cover layer and electrically connects to a p-type electrode. The p-type contact layer can be consisted of p-AlₓGa₁₋ₓN, wherein 0≦x≦0.15.

When an appropriate forward bias voltage is applied to the n-type electrode and the p-type electrode, the light emitting layer will be excited such that emits a 300˜380 nm UV light.

### BRIEF DESCRIPTION OF THE DRAWINGS

FIG. 1 is a diagram showing the conventional white light LED.

FIG. 2 is a diagram showing an LED according to the invention.

FIG. 3 shows an electroluminescence spectrum of LED lamp which uses an LED according to the invention.

FIG. 4 is a diagram showing a structure which disposes an R/G/B and InGaN quantum well/quantum dot excited light emitting layer on an LED according to the invention.

FIG. 5 is a diagram showing a structure which uses a UV light from an LED according to the invention to excite a visible light LED.

FIG. 6 is a diagram showing a structure in which an LED shown in FIG. 4 is disposed on the LED shown in FIG. 5.

FIG. 7 to FIG. 10 show light emitting frequency spectrums for red light, green light, blue light and white light, which are produced by using the UV light produced according to the invention to excite red light luminescent gel, green light luminescent gel, blue light luminescent gel and red/green/blue mixed luminescent gel respectively.

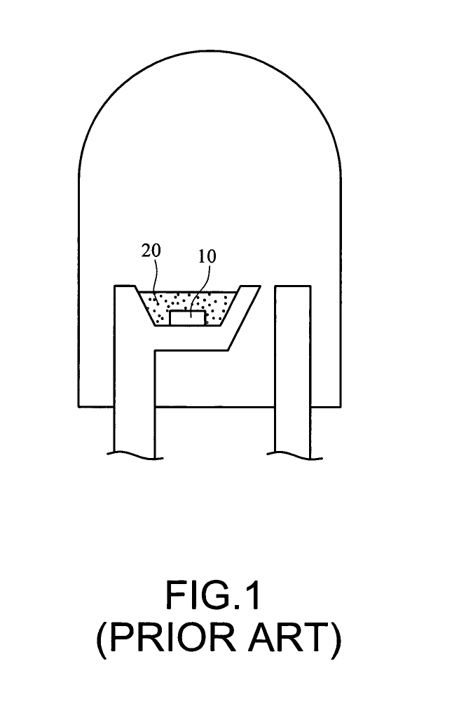

### DETAILED DESCRIPTION

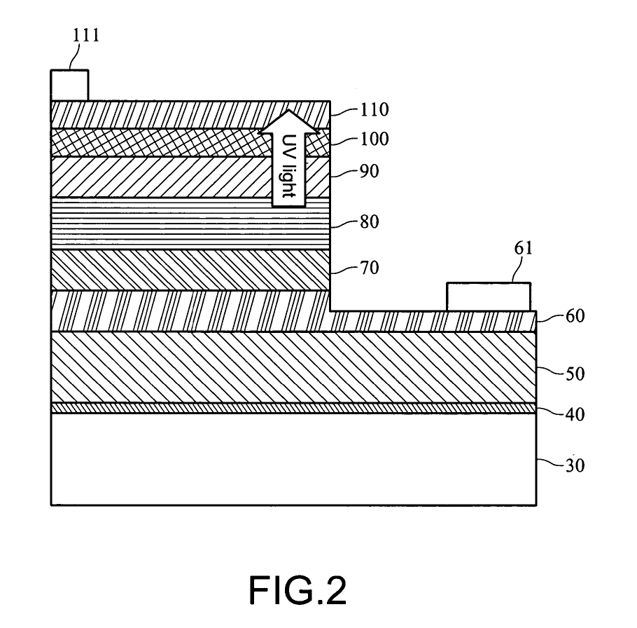

Please refer to FIG. 2, it is a diagram of light emitting diode according to the invention. Every layer of InGaN light emitting diode is added aluminum element to increase the energy gap and the effect of carrier injection. On the other hand, it can prevent light absorption effect. The amount of aluminum element can be adjusted to produce a 300˜380 nm UV light. An UV light with this region of wavelength can not be seen by humans.

Because human can not see the color emitted when a 300˜380 nm LED is light on (that is, a color that an LED expected to excite will not be affected), the LED can collocate luminescent materials with different wavelengths or have a quantum well/quantum dot structure on top layer to produce different colors (wavelengths) of lights.

A light emitting diode according to the invention comprises: a substrate 30, a nucleation layer 40, a buffer layer 50, a n-type contact layer 60, a n-type cover layer 70, a light emitting layer 80, a p-type barrier layer 90, a p-type cover layer 100 and a p-type contact layer 110.

The substrate 100 selected needs to fit for the epitaxy. For example, it can be a sapphire (Al₂O₃) substrate, a Si substrate, a SiC substrate, a GaN substrate, an AlN substrate, an AlGaN substrate and a ZnO substrate.

The nucleation layer 40 is formed on the substrate 30 and consisted of AlₓGa₁₋ₓN for preventing from the un-match of crystal lattice, wherein 0≦x≦1.

The buffer layer 50 is formed on the nucleation layer 40. It can be consisted of ud-AlₓGa₁₋ₓN or n-AlₓGa₁₋ₓN, wherein 0≦x≦0.3.

The n-type contact layer 60 is formed on the buffer layer 50 and electrically connects to an n-type electrode which is disposed thereon. The n-type contact layer 60 is consisted of n-AlₓGa₁₋ₓN, wherein 0≦x≦0.3.

The n-type cover layer 70 is formed on the n-type contact layer 60 for confining carriers. It can be consisted of n-AlₓGa₁₋ₓN, wherein 0≦x≦0.3.

The light emitting layer 80 is formed on the n-type cover layer 70, which is used for emitting light in the LED. The light emitting layer can be an In_{y}AlₓGa_{1-x-y}N/In_{y}AlₓGa_{1-x-y}N quantum well/quantum dot structure, wherein 0≦x≦0.3, 0≦y≦0.2.

The p-type barrier layer 90 is formed on the light emitting layer 80 for preventing carriers from overflowing. The p-type barrier layer 90 can be consisted of p-AlₓGa₁₋ₓN, wherein 0≦x≦0.4.

The p-type cover layer 100 is formed on the p-type barrier layer 90 for confining carriers and can be consisted of p-AlₓGa₁₋ₓN, wherein 0≦x≦0.3.

The p-type contact layer 110 is formed on the p-type cover layer 100 and there is a p-type electrode 111 thereon. The p-type contact layer 110 can be consisted of p-AlₓGa₁₋ₓN, wherein 0≦x≦0.15.

When an appropriate forward bias voltage is applied to the n-type electrode 61 and the p-type electrode 111, the luminescent will be excited through the epitaxy structure such that emits a 300˜380 nm UV light.

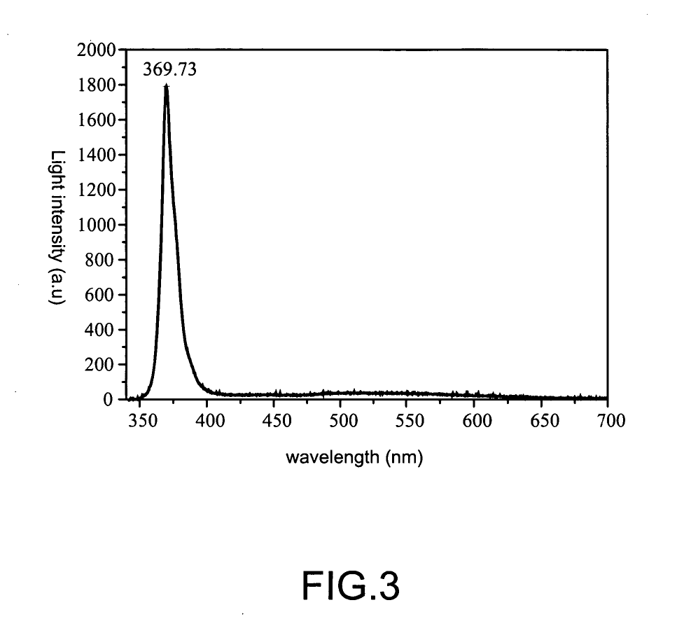

Please refer to FIG. 3, it shows a frequency spectrum of electroluminescence of LED lamp which uses an LED according to the invention. According to the drawing, the wavelength of light emitted from the LED is between about 200 nm and about 400 nm, and the major wavelength is about 369.73 nm.

This 300 nm˜380 nm UV light does nothing about the human feelings of colors. However, this LED can be used to match luminescent materials with different wavelengths or have a quantum well/quantum dot structure on top layer to produce different LEDs with different colors (wavelengths) of lights.

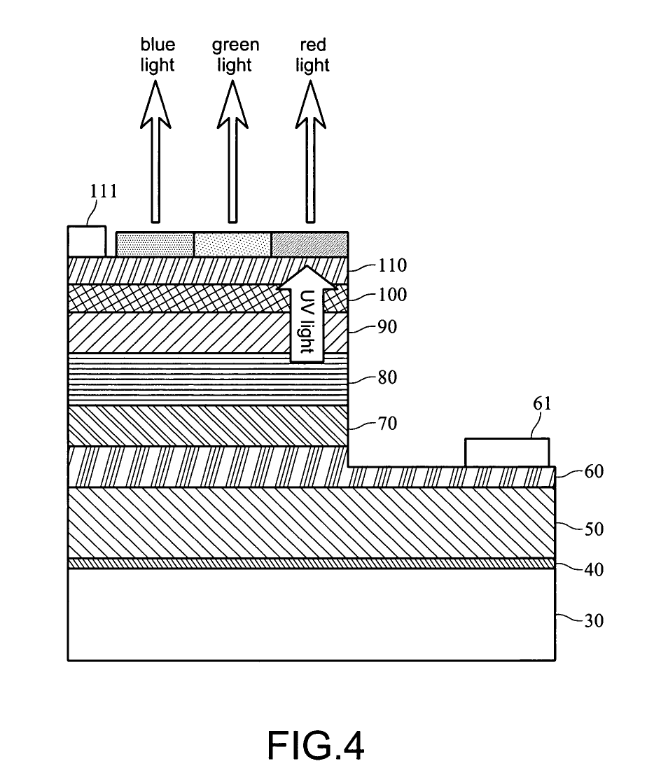

Please refer to FIG. 4, it shows a device which includes a red/green/blue and InGaN quantum well/quantum dot excited light emitting layer 120 on an LED according to the invention. The red/green/blue and InGaN quantum well/quantum dot excited light emitting layer 120 is excited by UV light produced from the lower LED to generate blue, red and green light, such that a white light is formed after the three excited lights mix together.

Because the blue, red and green lights are produced from the same chip and the same quantum well/quantum dot light emitting layer of one device, it has better chromaticity when compared to the conventional light source which uses three independent LEDs. It should be realized that this quantum well/quantum dot excited light emitting layer can be any kind of quantum well/quantum dot structure that produces single light wavelength for different colors (wavelengths) LED.

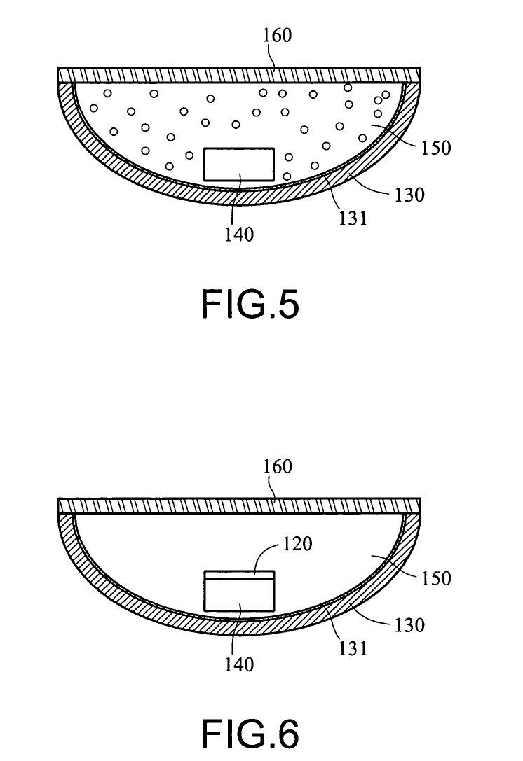

Please refer to FIG. 5, it shows a structure which is excited to produced a visible light by a UV light which is produced from an LED according to the invention.

The LED comprises: a substrate 130, an LED chip 140, a luminescent gel 150 and a total reflection sheet 160.

It can further comprise a total reflection film 131 which is formed on the substrate 130. The total reflection film 131 can be a optical reflection film or photo crystal coating film which is able to total reflect the UV light and be penetrated by the vision light. Shape of the substrate 130 is not limited to the bowl type, in other words, the LED chip 140 can apply to various kinds of substrates by the desire.

The LED chip 140 is disposed on the substrate 130, which is added aluminum element into each film of InGaN LED for emitting 300˜380 wavelength light. This LED chip 140 can be driven by applied current to emit UV light, which provides the luminescent gel 150 a light source to excite.

Periphery of the LED chip 140 is coated with luminescent gel 150 for producing fluorescence. The luminescent gel 150 is consisted of luminescent materials and epoxies. When a UV light generated by the LED chip 140 penetrates through the luminescent gel 150, luminescent materials will be excited and emit a second visible light, which is the fluorescence light.

It should be realized that the spectrum of emitting visible light of the luminescent material used in LED is determined according to the wavelength of light from the LED chip. Different LED chips need different luminescent materials which correspond to the light wavelength to produce fluorescence light.

The LED chip 140 used is an UV light LED chip. User can use different colors of luminescent gel 150 to match the chip 140 to emit different colors of light, such as red, yellow, green, and white. Besides, using blue LED to match yellow, green, red luminescent gel also can generate white, green, red and other colors of lights respectively.

Because the total reflection sheet 160 outside the luminescent gel can reflect the UV light totally, UV light will be confined in the luminescent gel 150 and produce repeatable, multi-direction reflection, which is similar to effect of the Fabry-Perot resonance chamber structure. By the multiple reflection of UV light in the resonance chamber, the UV light will excite the luminescent gel at the most, which exhausts the energy of UV light and produces more light. The total reflection sheet 160 can be produced by an optical film coating process or a photo crystal coating process.

In addition, by the design of some specific visible wavelength of fluorescence light, the quantity of light penetrating through the total reflection sheet 160 can be controlled, which accomplishes the purpose of controlling color temperature and brightness.

Please refer to FIG. 6, the LED structure shown in FIG. 4 is disposed on the structure shown in FIG. 5. Thus, the luminescent gel 150 is no more needed. Different colors (wavelengths) of LED is also can be formed by adjusting the composition of InGaN quantum well/quantum dot light emitting structure.

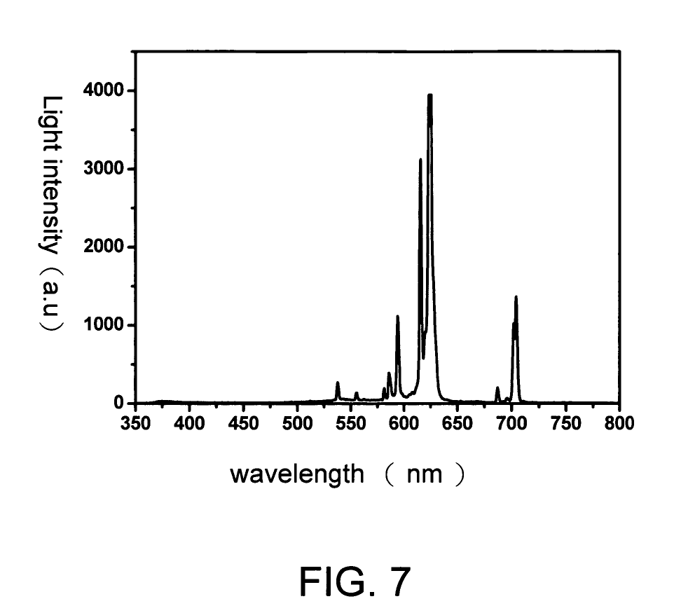

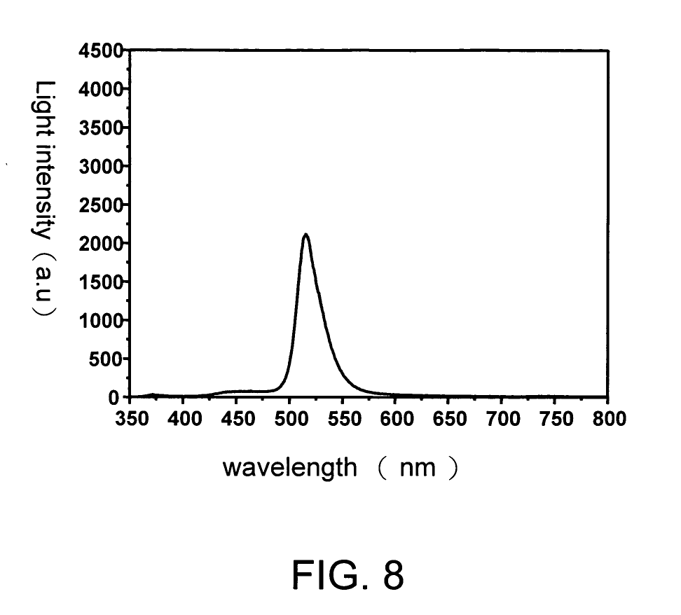

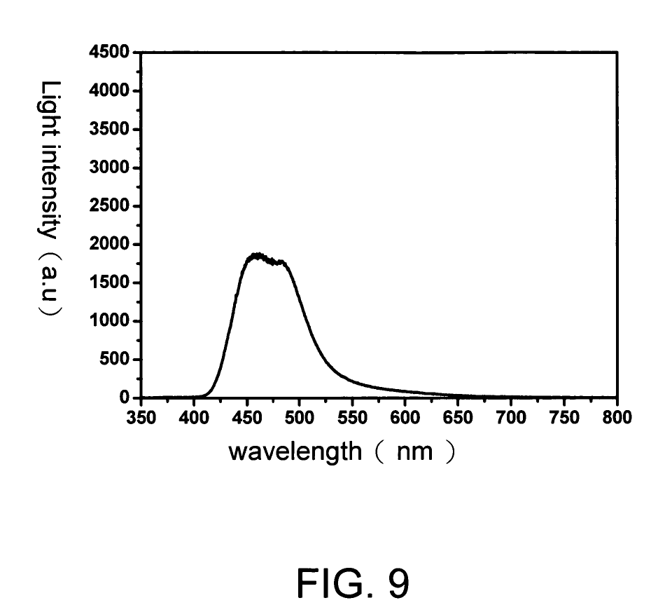

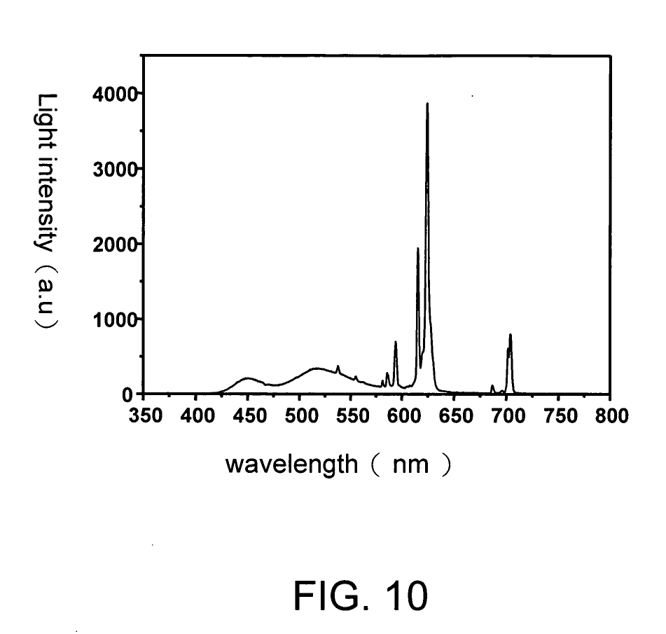

Please refer to FIG. 7 to FIG. 10, they show light emitting frequency spectrums for red light, green light, blue light and white light, which are produced by using the UV light produced according to the invention to excite red light luminescent gel, green light luminescent gel, blue light luminescent gel and red/green/blue mixed luminescent gel respectively. Thus indeed, using an LED according to the invention and a corresponding color (wavelength) of luminescent materials is able to excite and form different colors of light separately.

Although the invention has been described with reference to specific embodiments, this description is not meant to be construed in a limiting sense. Various modifications of the disclosed embodiments, as well as alternative embodiments, will be apparent to persons skilled in the art. It is, therefore, intended that the appended claims will cover all modifications that fall within the true scope of the invention.

What is claimed is:

1. A light emitting diode (LED), comprising:
a substrate;
a nucleation layer, which is formed on the substrate, and consisted of AlₓGa₁₋ₓN for preventing from the un-match of crystal lattice, wherein 0≦x≦1;
a buffer layer, which is formed on the nucleation layer;
a n-type contact layer, which is formed on the buffer layer and electrically connects to a n-type electrode, wherein the n-type contact layer is consisted of n-AlₓGa₁₋ₓN, wherein 0≦x≦0.3;
a n-type cover layer, which is formed on the n-type contact layer and consisted of n-AlₓGa₁₋ₓN, wherein 0≦x≦0.3;
a light emitting layer, which is formed on the n-type cover layer;
a p-type barrier layer, which is formed on the light emitting layer for preventing carriers from overflowing and consisted of p-AlₓGa₁₋ₓN, wherein 0≦x≦0.4;
a p-type cover layer, which is formed on the p-type barrier layer for confining the carriers and consisted of p-AlₓGa₁₋ₓN, wherein 0≦x≦0.3; and
a p-type contact layer, which is formed on the p-type cover layer and electrically connects to a p-type electrode, wherein the p-type contact layer is consisted of p-AlₓGa₁₋ₓN, wherein 0≦x≦0.15;
wherein, when an appropriate forward bias voltage is applied to the n-type electrode and the p-type electrode, the light emitting layer will be excited such that emits an UV light having wavelength between about 300˜380 nm.

2. The light emitting diode (LED) of claim 1, wherein the light emitting layer is selected form one group consisted of an In_{y}AlₓGa_{1-x-y}N/In_{y}AlₓGa_{1-x-y}N quantum well and an In_{y}AlₓGa_{1-x-y}N/In_{y}AlₓGa_{1-x-y}N quantum dot structure, wherein 0≦x≦0.3, 0≦y≦0.2.

3. The light emitting diode (LED) of claim 1, wherein the substrate is selected from one group consisted of a Al₂O₃ substrate, a Si substrate, a SiC substrate, a GaN substrate, a AlN substrate, a AlGaN substrate and a ZnO substrate.

4. The light emitting diode (LED) of claim 1, wherein the buffer layer is consisted of ud-AlₓGa₁₋ₓN, wherein 0≦x≦0.3.

5. The light emitting diode (LED) of claim 1, wherein the buffer layer is consisted of n-AlₓGa₁₋ₓN, wherein 0≦x≦0.3.

6. The light emitting diode (LED) of claim 1, further comprising an InGaN quantum well/quantum dot excited light emitting layer on the p-type contact layer, which produces different colors of light by using the UV light to excite it.

7. A structure of using a UV light from a light emitting diode (LED) to excite a visible light LED, comprising:
a first substrate;
at least one LED chip, which is disposed on the substrate to emit light from one emission face, comprising:
a second substrate;
a nucleation layer, which is formed on the second substrate, and consisted of AlₓGa₁₋ₓN for preventing from the un-match of crystal lattice, wherein 0≦x≦1;
a buffer layer, which is formed on the nucleation layer;
a n-type contact layer, which is formed on the buffer layer and electrically connects to a n-type electrode, wherein the n-type contact layer is consisted of n-AlₓGa₁₋ₓN, wherein 0≦x≦0.3;
a n-type cover layer, which is formed on the n-type contact layer and consisted of n-AlₓGa₁₋ₓN, wherein 0≦x≦0.3;
a light emitting layer, which is formed on the n-type cover layer;
a p-type barrier layer, which is formed on the light emitting layer for preventing carriers from overflowing and consisted of p-AlₓGa₁₋ₓN, wherein 0≦x≦0.4;
a p-type cover layer, which is formed on the p-type barrier layer for confining the carriers and consisted of p-AlₓGa₁₋ₓN, wherein 0≦x≦0.3; and
a p-type contact layer, which is formed on the p-type cover layer and electrically connects to a p-type electrode, wherein the p-type contact layer is consisted of p-AlₓGa₁₋ₓN, wherein 0≦x≦0.15; wherein, when an appropriate forward bias voltage is applied to the n-type electrode and the p-type electrode, the light emitting layer will be excited such that emits an UV light having wavelength between about 300˜380 nm;
a luminescent gel, which is consisted of a luminescent material and a epoxy and coating on the periphery, wherein when the light produced from the LED chip penetrates through the luminescent gel, the light excites the luminescent material to produce a fluorescence; and
a total reflection sheet, which is disposed on one side of the first substrate opposite to the luminescent gel, wherein when the light produced from the LED chip penetrates through the luminescent gel, the light excites the luminescent material to produce a fluorescence, and the total reflection sheet confines the light in the luminescent gel which produced a repeatable and multi direction reflection, improving efficiency of the light transforming.

8. The structure of claim 7, further comprising a photo crystal coating film which total reflects the UV light and is penetrated by the visual light.

9. The structure of claim 7, further comprising an optical reflective film which total reflects the UV light and is penetrated by the visual light.

10. The structure of claim 7, wherein the light emitting layer is selected form one group consisted of an In_{y}AlₓGa_{1-x-y}N/In_{y}AlₓGa_{1-x-y}N quantum well and an In_{y}AlₓGa_{1-x-y}N/In_{y}AlₓGa_{1-x-y}N quantum dot structure, wherein 0≦x≦0.3, 0≦y≦0.2.

11. The structure of claim 7, wherein the substrate is selected from one group consisted of an Al₂O₃ substrate, a Si substrate, a SiC substrate, a GaN substrate, an AlN substrate, an AlGaN substrate and a ZnO substrate.

12. The structure of claim 7, wherein the buffer layer is consisted of ud-AlₓGa₁₋ₓN, wherein 0≦x≦0.3.

13. The structure of claim 7, wherein the buffer layer is consisted of n-AlₓGa₁₋ₓN, wherein 0≦x≦0.3.

14. The structure of claim 7, further comprising an InGaN quantum well/quantum dot excited light emitting layer on the p-type contact layer, which produces different colors of light by using the UV light to excite it.

15. The structure of claim 7, wherein the LED chip is a UV light LED chip, which co-operate different colors of the luminescent gel to excite different colors of light.

16. The structure of claim 7, wherein the LED chip is a blue light LED chip, which co-operate yellow lights of the luminescent gel to excite white light.

17. The structure of claim 7, wherein the LED chip is a blue light LED chip, which co-operate red lights of the luminescent gel to excite red light.

18. The structure of claim 7, wherein the LED chip is a blue light LED chip, which co-operate green lights of the luminescent gel to excite green light.
